(19) United States
(12) Patent Application Publication
(10) Pub. No.: US 2015/0160311 A1
(43) Pub. Date: Jun. 11, 2015

(54) CAPSULE FOR A PNEUMATIC SAMPLE FEEDWAY

(71) Applicant: ASPECT IMAGING LTD, Shoham (IL)

(72) Inventors: Uri RAPOPORT, Moshav Ben Shemen (IL); Itzchak RABINOVITZ, Ness Tsiyona (IL)

(21) Appl. No.: 14/626,391

(22) Filed: Feb. 19, 2015

Related U.S. Application Data
(63) Continuation-in-part of application No. 13/954,388, filed on Jul. 30, 2013, now Pat. No. 8,992,132.

(30) Foreign Application Priority Data
Aug. 15, 2012 (IL) 221494

(51) Int. Cl. G01R 33/30; B65G 51/22; B65G 51/04

(52) U.S. Cl. CPC G01R 33/307; B65G 51/04; B65G 51/22

(57) ABSTRACT

A pneumatic sample feedway embeddable into a magnetic resonance imaging (MRI) device. The pneumatic sample feedway includes: a plurality of capsules configured for enclosing biological tissue samples; and a conductor pipe connectable to a source of a compressed fluid. The pipe is configured to receive a train of capsules and pneumatically forward the capsules into the MRI device.

### FIELD OF THE INVENTION

The present invention relates to a capsule for a pneumatic tube transport and, more specifically, to a capsule configured to hold a biological sample for a pneumatic sample feedway for a magnetic resonance imaging device.

### BACKGROUND OF THE INVENTION

Pneumatic tubes are physical transport systems in which cylindrical containers are propelled through a network of tubes by compressed air or by a vacuum. The containers are vehicles for transporting physical objects. Pneumatic tubes were also briefly considered for a subway-like transportation of people, as well as a long-distance postal service.

### SUMMARY OF THE INVENTION

It is hence one object of the invention to disclose a pneumatic sample feedway embeddable into a magnetic resonance imaging (MRI) device. The aforesaid feedway comprises: (a) a plurality of capsules configured for enclosing a biological tissue samples; and (b) a conductor (drive) pipe connectable to a source of a compressed fluid. The pipe is configured for receiving a train of the capsules and pneumatically forwarding thereof into the MRI device. The pipe has a proximal terminal and distal terminal. The proximal is configured for loading the train of capsules into the pipe. Importantly, said capsules comprising at least one inwardly protrusion element for anchoring said at least one biological tissue sample.

It is also in the scope of the invention wherein the distal termination possibly provided with a catch lock device. The lock device is configured for locking the train of capsules, when a capsule contained in a magnetic field is measured, and opening the catch lock device such that the train of capsules is displaced within the pipe and a next capsule is fed for measurement.

Another object of the invention is to disclose a drive of the catch lock device selected from the group consisting of a mechanical drive, a pneumatic drive, an electromagnetic drive and any combination thereof.

A further object of the invention is to disclose a method of feeding of samples to an MRI device. The aforesaid method comprises the steps of (a) providing a pneumatic sample feedway embeddable into a magnetic resonance imaging (MRI) device; the feedway comprising: (i) a plurality of capsules configured for enclosing a biological tissue samples; (ii) a conductor (drive) pipe connectable to a source of a compressed fluid; the pipe configured for receiving the a train of the capsules and pneumatically forwarding thereof into the MRI device; the pipe having a proximal terminal and distal terminal; the proximal configured for loading the train of capsules into the pipe; the distal termination is provided with a catch lock device; the lock device is configured for locking the train of capsules when a capsule contained in a magnetic field is measured and opening the catch lock device such that the train of capsules is displaced within the pipe and next capsule is fed for measurement; (b) preparing samples to be measured by means of MRI device; (c) placing the samples into sample capsules; (d) loading the capsules into the pipe one by one (train); (e) feeding the capsules into a magnetic field of the MRI device.

It is another core purpose of the invention to provide the step of feeding the capsules comprising a step of discreetly displacing of the train of capsules such that the capsule train is locked, when a capsule contained in a magnetic field is measured, and displaced for one capsule distance between measurements.

It is another core purpose of the invention to provide the step of step of providing a pneumatic sample feedway embeddable into a magnetic resonance imaging (MRI) device, further comprising a step of providing said plurality of capsules with at least one inwardly protrusion element for anchoring said at least one biological tissue sample; and said step of placing said samples into said sample capsules comprises a step of anchoring said sample using said at least one inwardly protrusion element.

A further object of the invention is to disclose the step of discreetly displacing of the train of capsules performed by a drive of the catch lock device is selected from the group consisting of a mechanical drive, a pneumatic drive, an electromagnetic drive and any combination thereof.

It is further object to the present invention to disclose the capsule having a main longitudinal axis L:L and said at least one element is characterized by: being arranged substantially coplanar along their cross-section; being arranged substantially perpendicular to said main longitudinal axis L:L; or, being arranged substantially parallel to cross-section of said capsule.

It is further object to the present invention to disclose at least one element that is arranged substantially non-planar along their cross-section.

It is further object to the present invention to disclose the capsule having a main longitudinal axis L:L and said at least one element is characterized by: being arranged substantially coplanar along their cross-section; being arranged substantially parallel to said main longitudinal axis L:L; or being arranged substantially perpendicular to cross-section of said capsule.

It is further object to the present invention to disclose at least one element that is arranged substantially non-planar along their cross-section.

It is another object of the present invention to disclose at least one element further comprising a sub-element selected from a group consisting of: a hook, a grip, forceps, pliers, basket, flaps, wings, bulges, cushions, wires, tweezers, jaws and any combination thereof.

It is another object of the present invention to disclose at least one element is coupled to the inner surface of said capsule.

It is another object of the present invention to disclose a sample that is confined by means of said at least one element and said inner surface of said capsule.

It is another object of the present invention to disclose in a capsule for use in a pneumatic sample feedway embeddable into a magnetic resonance imaging (MRI) device comprising a conductor (drive) pipe connectable to a source of a compressed fluid; said pipe configured for receiving a train of at least one capsule and pneumatically forwarding thereof into said MRI device; said pipe having a proximal terminal and distal terminal; said proximal configured for loading said train of at least one capsules into said pipe; at least one inwardly protruding element for anchoring at least one biological tissue samples thereof.

### BRIEF DESCRIPTION OF THE DRAWINGS

In order to understand the invention and to see how it may be implemented in practice, a plurality of embodiments is adapted to now be described, by way of non-limiting example only, with reference to the accompanying drawings, in which

FIG. 1 is a schematic view of a pneumatic sample feedway;

FIG. 2 is a schematic view of the feedway embedded into MRI device;

FIG. 3 is a schematic view of a pneumatic arrangement of the sample feedway; and

FIG. 4 is a schematic view of a sample capsule.

FIG. 5 is a schematic view of a sample capsule with a sample holder and closed lids.

FIG. 6 is a schematic view of a sample capsule with a sample holder and open lids.

FIG. 7 is a schematic view of an embodiment of a capsule with sample holder in which depicted in the figure is the main longitudinal axis L:L of the capsule.

FIG. 8 is a schematic view of an embodiment of a capsule with sample holder in which depicted at the end of the element there is a sub-element in a form of grips.

FIG. 9 is a schematic view of an embodiment of a capsule with sample holder in which depicted at the end of the element there is a sub-element in a form of a basket held by the elements in the center of the capsule.

FIG. 10 is a schematic view of an embodiment of a capsule with sample holder in which depicted at the end of the element there is a sub-element in a form of hooks.

FIG. 11 is a schematic view of an embodiment of a capsule with sample holder in which depicted at the end of the element there is a sub-element in a form of a basket.

FIG. 12 is a schematic view of an embodiment of a capsule with sample holder in which depicted at the end of the element there is a sub-element in a form of a spring in which the sample can be inserted or lodged.

FIG. 13 is a schematic view of an embodiment of a capsule with sample holder in which depicted an embodiment similar to the one depicted in FIG. 11, but instead of a basket there is a grip.

### DETAILED DESCRIPTION OF THE INVENTION

The following description is provided, so as to enable any person skilled in the art to make use of the invention and sets forth the best modes contemplated by the inventor of carrying out this invention. Various modifications, however, are adapted to remain apparent to those skilled in the art, since the generic principles of the present invention have been defined specifically to provide a pneumatic sample feedway embeddable into a magnetic resonance imaging (MRI) device and a method of using the same.

The term “pneumatic pipe” hereinafter refers to a system in which cylindrical capsules are propelled through the pipe by a compressed fluid.

The term “sample capsule” hereinafter refers to a magnetically transparent shell configured for receiving a sample to be measured within an MRI device.

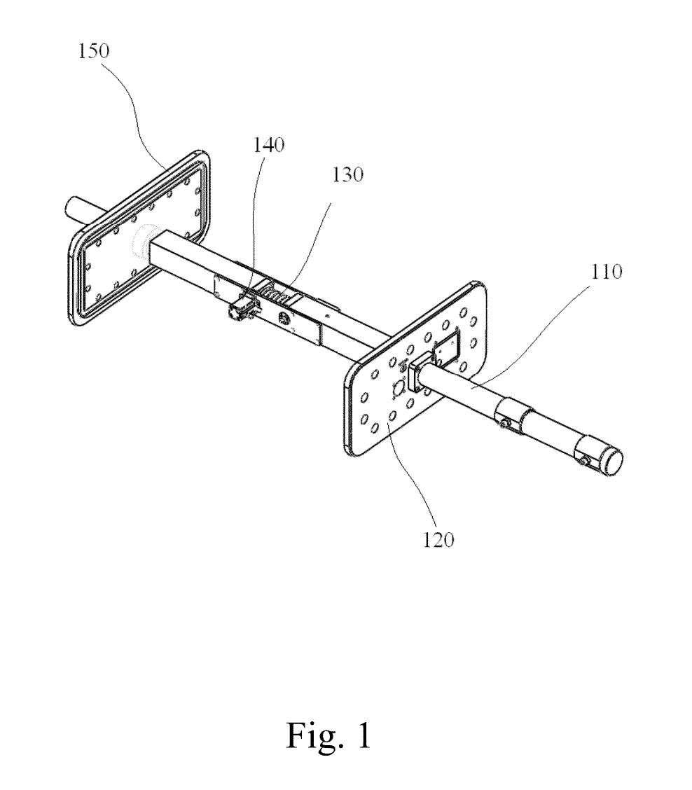

Reference is now made to FIG. 1, presenting a pneumatic sample feedway adapted for embedding into an MRI device (not shown). The feedway comprises a pipe 110 in which a plurality of sample capsules (not shown) are loaded in a train-like manner. In accordance with one embodiment of the present invention, the pipe can be provided with an internal spring for forcing a train of the sample capsules through the pipe 110. A receptacle 130 is designed for receive the sample capsule to be measured. A catch lock device 140 locks the train of capsules when a capsule contained in the pneumatic cylinder 130 is measured. During a time period when catch lock device 140 is opened, the train of capsules is displaced within said pipe and next capsule is fed for measurement. Plates 120 and 150 are designed for mounting the feedway onto the MRI device.

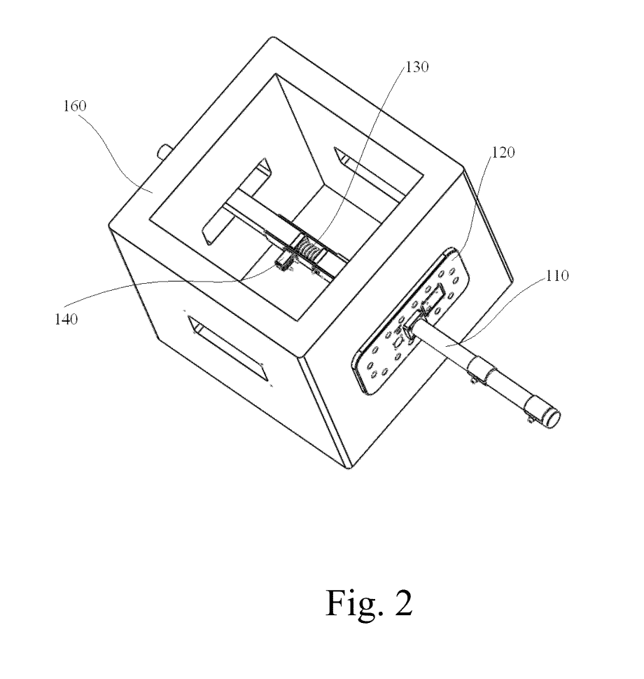

Reference is now made to FIG. 2, schematically showing the sample feedway embedded into a housing 160 of the MRI device. As seen FIG. 2, the plates 120 and 150 the sample feedway are mechanically secured to the housing 160.

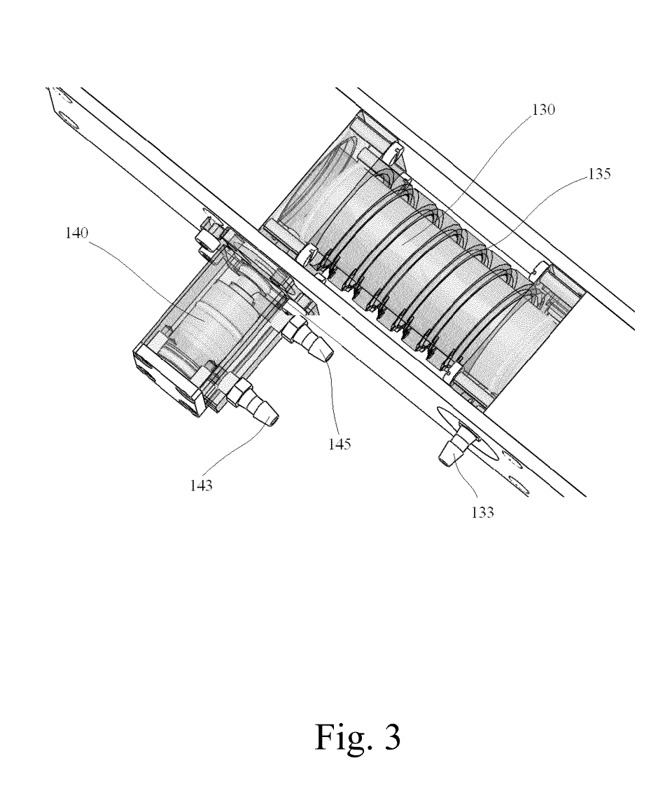

Reference is now made to FIG. 3, showing an enlarged view of pneumatic arrangement of the present invention. The pneumatic cylinder 130 is accommodated within a measuring coil 135. A fitting 133 is designed for feeding a compressed fluid to the cylinder 130. Specifically, the fluid fed into the cylinder expulses the sample capsule from the cylinder 130 after measurement. When the measured capsule is expulsed from the cylinder 130, a next capsule in the train of capsules is displaced into the cylinder 130. Synchronically to this, the catch lock device locks the cylinder 140. According to on embodiment of the present invention, the catch lock device comprises a pneumatically driven bar (not shown). Fittings 143 and 145 are designed for feeding a compressed fluid creating a force which locks and opens the cylinder 140.

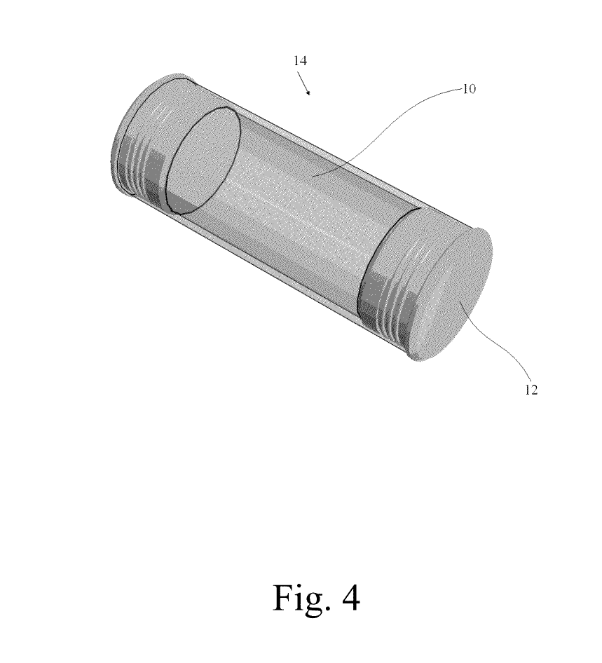

Reference is now made to FIG. 4, presenting an exemplary sample capsule 14 comprising a tubular member 10 and end caps 12. The sample capsule should be magnetically transparent and biologically neutral.

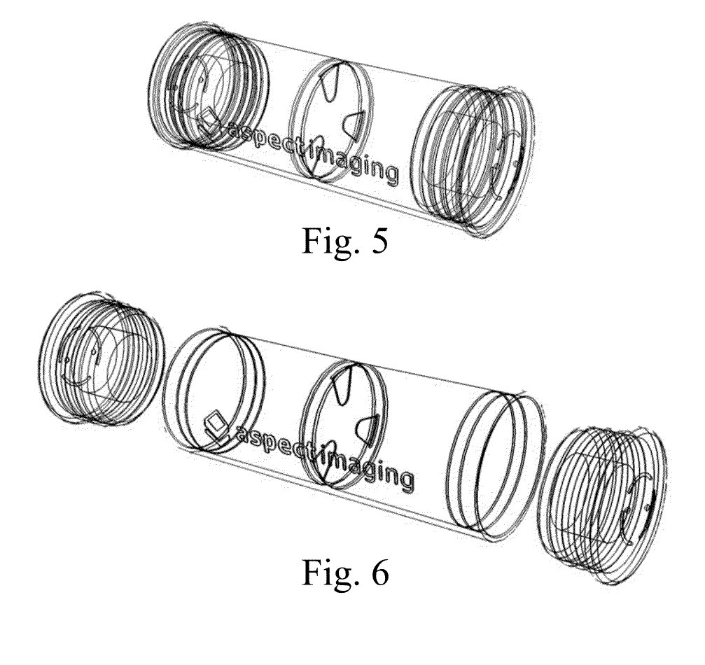

Reference is now made to FIGS. 5 and 6, presenting an exemplary sample capsule 14 comprising a tubular member 10, end caps 12 and an example of a sample holder 11. The sample capsule and all its elements should be magnetically transparent and biologically neutral.

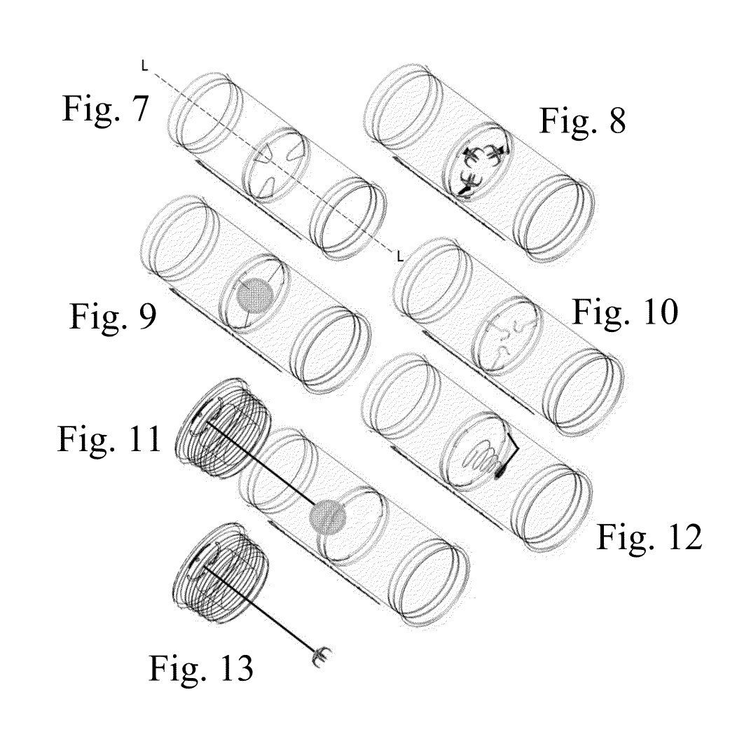

Reference is now made to FIGS. 7-13, presenting a series of exemplary sample capsules comprising a variety of examples of sample holders. Also depicted in the figure is the main longitudinal axis L:L of the capsule (FIG. 7), which is intended to be considered the same for all other capsule examples in this application. The sample capsule and all its elements should be magnetically transparent and biologically neutral. FIG. 8 presents an embodiment where at the end of the element there is a sub-element in a form of grips. FIG. 9 presents an embodiment where at the end of the element there is a sub-element in a form of a basket held by the elements in the center of the capsule. FIG. 10 presents an embodiment where at the end of the element there is a sub-element in a form of hooks. FIG. 11 presents an embodiment where at the end of the element there is a sub-element in a form of a basket. In this case the element is attached to the cap of the capsule. FIG. 12 presents an embodiment where at the end of the element there is a sub-element in a form of a spring in which the sample can be inserted or lodged. FIG. 13 presents an embodiment similar to the one depicted in FIG. 11, but instead of a basket there is a grip. All these embodiments are intended to be examples only and should not limit the invention in any way.

In accordance with the embodiments of the present invention, the sample holder may comprise one single element or a multiplicity of elements. The elements can be attached to the inner surface of the capsule or to the end cap. The elements may or may not be selected from a group consisting of: a hook, a grip, forceps, pliers, basket, flaps, wings, bulges, cushions, wires, tweezers, jaws and any combination thereof.

In accordance with the embodiments of the present invention, the sample may or may not be in contact with the inner surface of the capsule.

In accordance with one embodiment of the present invention, a pneumatic sample feedway embeddable into a magnetic resonance imaging (MRI) device is disclosed. The aforesaid feedway (a) a plurality of capsules configured for enclosing a biological tissue samples; and (b) a conductor (drive) pipe connectable to a source of a compressed fluid. The pipe is configured for receiving a train of the capsules and pneumatically forwarding thereof into the MRI device. The pipe has a proximal terminal and distal terminal. The proximal is configured for loading the train of capsules into the pipe.

It is a core feature of the invention to provide the distal termination provided with a catch lock device. The lock device is configured for locking the train of capsules, when a capsule contained in a magnetic field is measured, and opening the catch lock device such that the train of capsules is displaced within the pipe and a next capsule is fed for measurement.

In accordance with another embodiment of the present invention, a drive of said catch lock device is selected from the group consisting of a mechanical drive, a pneumatic drive, an electromagnetic drive and any combination thereof.

In accordance with one embodiment of the present invention, a method of feeding of samples to an MRI device is disclosed. The aforesaid method comprises the steps of (a) providing a pneumatic sample feedway embeddable into a magnetic resonance imaging (MRI) device; the feedway comprising: (i) a plurality of capsules configured for enclosing a biological tissue samples; (ii) a conductor (drive) pipe connectable to a source of a compressed fluid; the pipe configured for receiving the a train of the capsules and pneumatically forwarding thereof into the MRI device; the pipe having a proximal terminal and distal terminal; the proximal configured for loading the train of capsules into the pipe; the distal termination is provided with a catch lock device; the lock device is configured for locking the train of capsules when a capsule contained in a magnetic field is measured and opening the catch lock device such that the train of capsules is displaced within the pipe and next capsule is fed for measurement; (b) preparing samples to be measured by means of MRI device; (c) placing the samples into sample capsules; (d) loading the capsules into the pipe one by one (train); (e) feeding the capsules into a magnetic field of the MRI device.

It is another core feature of the invention to provide the step of feeding the capsules comprising a step of discreetly displacing of the train of capsules such that the capsule train is locked, when a capsule contained in a magnetic field is measured, and displaced for one capsule distance between measurements.

In accordance with one embodiment of the present invention, the step of discreetly displacing of the train of capsules is performed by a drive of said catch lock device is selected from the group consisting of a mechanical drive, a pneumatic drive, an electromagnetic drive and any combination thereof.

What is claimed is:

1. A pneumatic sample feedway embeddable into a magnetic resonance imaging (MRI) device; said feedway comprising:
a. a plurality of capsules configured for enclosing at least one biological tissue sample; and
b. a conductor (drive) pipe connectable to a source of a compressed fluid; said pipe configured for receiving said a train of said capsules and pneumatically forwarding thereof into said MRI device; said pipe having a proximal terminal and distal terminal; said proximal configured for loading said train of capsules into said pipe;
wherein said capsules comprising at least one inwardly protrusion element for anchoring said at least one biological tissue sample.

2. The feedway according to claim 1, wherein said distal termination is provided with a catch lock device; said lock device is configured for locking said train of capsules when a capsule contained in a magnetic field is measured and opening said catch lock device such that said train of capsules is displaced within said pipe and next capsule is fed for measurement.

3. The feedway according to claim 1, wherein a drive of said catch lock device is selected from the group consisting of a mechanical drive, a pneumatic drive, an electromagnetic drive and any combination thereof.

4. A method of feeding of samples to an MRI device, said method comprising the steps of
a. providing a pneumatic sample feedway embeddable into a magnetic resonance imaging (MRI) device with a plurality of capsules configured for enclosing a biological tissue samples; and a conductor (drive) pipe connectable to a source of a compressed fluid; said pipe configured for receiving said a train of said capsules and pneumatically forwarding thereof into said MRI device; said pipe having a proximal terminal and distal terminal; said proximal configured for loading said train of capsules into said pipe; said distal termination is possibly provided with a catch lock device; said lock device is configured for locking said train of capsules when a capsule contained in a magnetic field is measured and opening said catch lock device such that said train of capsules is displaced within said pipe and next capsule is fed for measurement;
b. preparing samples to be measured by means of MRI device;
c. placing said samples into sample capsules;
d. loading said capsules into said pipe one by one (train); and
e. feeding said capsules into a magnetic field of said MRI device, said step of feeding said capsules possibly comprises a step of discreetly displacing of said train of capsules such that said capsule train is locked when a capsule contained in a magnetic field is measured and displaced for one capsule distance between measurements;
wherein said step of providing a pneumatic sample feedway embeddable into a magnetic resonance imaging (MRI) device further comprises a step of providing said plurality of capsules with at least one inwardly protrusion element for anchoring said at least one biological tissue sample; and
further wherein said step of placing said samples into said sample capsules comprises a step of anchoring said sample using said at least one inwardly protrusion element.

5. The method according to claim 3, wherein said step of discreetly displacing of said train of capsules is performed by a drive of said catch lock device is selected from the group consisting of a mechanical drive, a pneumatic drive, an electromagnetic drive and any combination thereof.

6. The feedway according to claim 1, wherein said capsule having a main longitudinal axis L:L and said at least one element is characterized by:
a. being arranged substantially coplanar along their cross-section;
b. being arranged substantially perpendicular to said main longitudinal axis L:L; or,
c. being arranged substantially parallel to cross-section of said capsule.

7. The feedway according to claim 6, wherein said at least one element is arranged substantially non-planar along their cross-section.

8. The feedway according to claim 1, wherein said capsule having a main longitudinal axis L:L and said at least one element is characterized by:
a. being arranged substantially coplanar along their cross-section;
b. being arranged substantially parallel to said main longitudinal axis L:L; or,
c. being arranged substantially perpendicular to cross-section of said capsule.

9. The feedway according to claim 8, wherein said at least one element is arranged substantially non-planar along their cross-section.

10. The feedway according to claim 1, wherein said at least one element further comprising a sub-element selected from a group consisting of: a hook, a grip, forceps, pliers, basket, flaps, wings, bulges, cushions, wires, tweezers, jaws and any combination thereof.

11. The feedway of claim 1, wherein said at least one element is coupled to the inner surface of said capsule.

12. The feedway of claim 1, wherein said sample is confined by means of said at least one element and said inner surface of said capsule.

13. In a capsule for use in a pneumatic sample feedway embeddable into a magnetic resonance imaging (MRI) device comprising a conductor (drive) pipe connectable to a source of a compressed fluid; said pipe configured for receiving a train of at least one capsule and pneumatically forwarding thereof into said MRI device; said pipe having a proximal terminal and distal terminal; said proximal configured for loading said train of at least one capsules into said pipe;
at least one inwardly protruding element for anchoring at least one biological tissue samples thereof.

14. The capsule according to claim 13, wherein said capsule having a main longitudinal axis L:L and said at least one element is characterized by:
a. being arranged substantially coplanar along their cross-section;
b. being arranged substantially perpendicular to said main longitudinal axis L:L; or,
c. being arranged substantially parallel to cross-section of said capsule.

15. The capsule according to claim 14, wherein said at least one element is arranged substantially non-planar along their cross-section.

16. The capsule according to claim 1, wherein said capsule having a main longitudinal axis L:L and said at least one element is characterized by:
a. being arranged substantially coplanar along their cross-section;
b. being arranged substantially parallel to said main longitudinal axis L:L; or,
c. being arranged substantially perpendicular to cross-section of said capsule.

17. The capsule according to claim 16, wherein said at least one element is arranged substantially non-planar along their cross-section.

18. The capsule according to claim 13, wherein said at least one element further comprising a sub-element selected from a group consisting of: a hook, a grip, forceps, pliers, basket, flaps, wings, bulges, cushions, wires, tweezers, jaws and any combination thereof.

19. The capsule of claim 13, wherein said at least one element is coupled to the inner surface of said capsule.

20. The capsule of claim 13, wherein said sample is confined by means of said at least one element and said inner surface of said capsule.
